(19) United States
(12) Patent Application Publication
(10) Pub. No.: US 2022/0147100 A1
(43) Pub. Date: May 12, 2022

(54) FOLDABLE COMPUTING DEVICE

(71) Applicant: Hewlett-Packard Development Company, L.P., Spring, TX (US)

(72) Inventors: Chalam Kashyap, Fort Collins, CO (US); Hung-Sung Pan, Taipei City (TW); Kuan-Ting Wu, Taipei City (TW)

(73) Assignee: Hewlett-Packard Development Company, L.P., Spring, TX (US)

(21) Appl. No.: 17/296,732

(22) PCT Filed: Jul. 25, 2019
(86) PCT No.: PCT/US2019/043402

§ 371 Date: May 25, 2021

(51) Int. Cl. G06F 1/16; H01L 41/083; H01L 41/09; H01F 7/02

(52) U.S. Cl. CPC G06F 1/1616; H01L 41/083; G06F 1/1679; H01F 7/02; H01L 41/0986

(57) ABSTRACT

A foldable computing device is described. The foldable computing device can include a power switch, a display screen unit including a first magnet, a base unit and an actuator. The base unit can include an assembly with a second magnet and a third magnet. The assembly can be at a first position that causes the first magnet of the display screen unit to attract to the second magnet of the assembly of the base unit to lock the display screen unit. The actuator can receive an electrical pulse when the power switch is selected to power on the foldable computing device and provide a motion to move the assembly to a second position, to cause the first magnet of the display screen unit to be moved away from the second magnet and repulse the third magnet of the assembly in the base unit to unlock the display screen unit.

### BACKGROUND

Computing devices, such as laptop computers, notebook computers, handheld game consoles, etc., can have a clamshell form factor, in which a display screen can be mounted on an inside of an upper lid and interface controls, such as a keyboard, buttons, etc. can be attached to an inside of a lower lid. The upper lid can fold with respect to the lower lid via a hinge. The upper lid can be opened to use the computing device, and the upper lid can be closed when the computing device is not in use, thereby protecting the display screen and the interface controls.

### BRIEF DESCRIPTION OF THE DRAWINGS

FIG. 1 illustrates an example of a foldable computing device having a switch that unlocks a display screen unit in accordance with the present disclosure;

FIG. 2 illustrates an example of a foldable computing device having pairs of magnets to unlock a display screen unit in accordance with the present disclosure;

FIG. 3A illustrates an example of a foldable computing device having magnets to lock a display screen unit based on an attraction force in accordance with the present disclosure;

FIG. 3B illustrates an example of a foldable computing device having magnets to unlock a display screen unit based on a repulsion force in accordance with the present disclosure;

FIG. 4A illustrates an example of a foldable computing device having pairs of magnets to lock a display screen unit based on an attraction force in accordance with the present disclosure;

FIG. 4B illustrates an example of a foldable computing device having pairs of magnets to unlock a display screen unit based on a repulsion force in accordance with the present disclosure;

FIG. 5 illustrates an example of a functionality of a piezoelectric actuator in accordance with the present disclosure;

FIG. 6 is a flowchart illustrating an example method of making a foldable computing device in accordance with the present disclosure; and

FIG. 7 is a flowchart illustrating an example method of unlocking a display screen unit in a foldable computing device in accordance with the present disclosure.

### DETAILED DESCRIPTION

The present disclosure describes a device as well as a method. An example of the present disclosure can include a foldable computing device. The foldable computing device can include a power switch. The foldable computing device can include a display screen unit including a first magnet. The foldable computing device can include a base unit electrically and mechanically coupled to the display screen unit. The base unit can include an assembly with a second magnet and a third magnet, wherein the assembly is at a first position that causes the first magnet of the display screen unit to attract to the second magnet of the assembly in the base unit to lock the display screen unit. The foldable computing device can include an actuator that receives an electrical pulse when the power switch is selected to power on the foldable computing device and provides a motion to move the assembly to a second position, to cause the first magnet of the display screen unit to be moved away from the second magnet and repulse the third magnet of the assembly in the base unit to unlock the display screen unit.

In one example, the first magnet can include a first pair of magnets, the second magnet can include a second pair of magnets, and the third magnet can include a third pair of magnets. In another example, the actuator can be a linear piezoelectric actuator that causes the motion produced by the actuator to be linear. In yet another example, the actuator can contract to move the assembly to the first position after the display screen unit is unlocked and opened, to enable the display screen unit to be locked when the first magnet becomes attracted to the second magnet of the assembly in the base unit. In a further example, the foldable computing device can be powered on and the display screen unit can be unlocked as a result of a single action of selecting the power switch to power on the foldable computing device. In yet a further example, the display screen unit can open by a defined amount when the display screen unit is unlocked. In one aspect, the first magnet can include a negative end that attracts to a positive end of the second magnet to lock the display screen unit. In another aspect, the first magnet can include a negative end that is repulses a negative end of the second magnet to unlock the display screen unit.

Another example of the present disclosure can include a method of making a foldable computing device. The method can include assembling a foldable computing device that includes a display screen unit and a base unit that is electrically and mechanically coupled to the display screen unit. The display screen unit can include a first magnet. The base unit can include an assembly with a second magnet and a third magnet, and the assembly can be at a first position to cause an attraction force between the first magnet of the display screen unit and the second magnet of the assembly in the base unit to lock the display screen unit. The method can include inserting an actuator in the base unit. The actuator can receive an electrical pulse when the foldable computing device is powered on and can provide a motion to move the assembly to a second position, to cause a repulsion force between the first magnet of the display screen unit and the third magnet of the assembly in the base unit to unlock the display screen unit.

Another example of the present disclosure can include a method of unlocking a display screen unit in a foldable computing device. The method can include receiving an electrical pulse at an actuator of the foldable computing device. The electrical pulse can be received when the foldable computing device is powered on. The foldable computing device can include the display screen unit that includes a first magnet and a base unit that includes an assembly with a second magnet and a third magnet. The electrical pulse can be received when the assembly is at a first position that causes the first magnet of the display screen unit to attract to the second magnet of the assembly in the base unit to lock the display screen unit. The method can include providing, in response to the electrical pulse received at the actuator, a motion to move the assembly in the base unit of the foldable computing device from the first position to a second position, to cause the first magnet of the display screen unit to move away from the second magnet and repulse the third magnet of the assembly in the base unit to unlock the display screen unit.

In these examples, it is noted that when discussing the device, the system, or the method, any of such discussions can be considered applicable to the other examples, whether or not they are explicitly discussed in the context of that example. Thus, for example, in discussing details about an autoclavable human interface device, such discussion also refers to the methods and systems described herein, and vice versa.

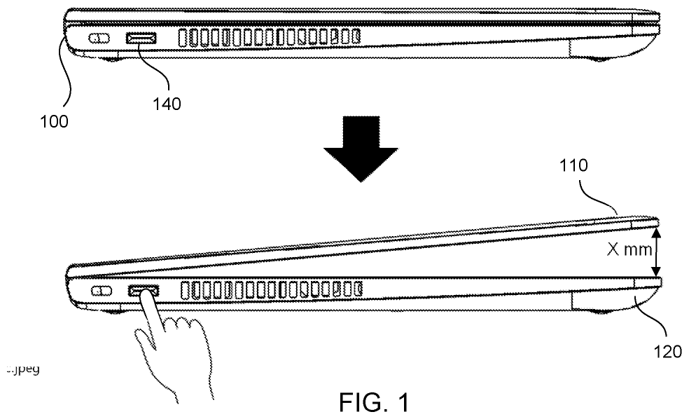

Turning now to the FIGS., FIG. 1 illustrates an example of a foldable computing device 100. The foldable computing device 100 can include, but is not limited to, a laptop computer, a notebook computer, a handheld game console, or a like computing device that includes a clamshell form factor, in which a display screen unit 110 can be attached to a base unit 120. The display screen unit 110 can include a display screen on an inside, and interface controls, such as a keyboard, buttons, etc. can be attached to an inside of the base unit 120. The display screen unit 110 can fold with respect to the base unit 120 via a hinge. The display screen unit 110 can be opened to use the foldable computing device 100, and the display screen unit 110 can be closed when the foldable computing device 100 is not in use.

In one example, the foldable computing device 100 can include a power button or switch 140 to power on/off or turn on/off the foldable computing device 100. In one example, when the power button or switch 140 is selected or pressed to power on or turn on the foldable computing device 100, the display screen unit 110 can become unlocked. The display screen unit 110 can open by a defined amount, such as X mm where X is a positive integer, when the display screen unit 110 is unlocked. In this example, the foldable computing device 100 can be powered on and the display screen unit 110 can be unlocked as a result of a single action of selecting the power button or switch 140 to power on or turn on the foldable computing device 100. Thus, the display screen unit 110 can initially be locked and closed when the foldable computing device 100 is shut off, and after the power button or switch 140 is selected to power on or turn on the foldable computing device 100, the display screen unit 110 can become unlocked and the display screen unit 110 can open by the defined amount.

In one example, foldable computing devices such as laptops and notebooks are becoming increasingly thinner and lighter as compared to past models. Opening a display of the foldable computing device using a single hand can be difficult, as the display can have a sufficient amount of torque on the hinges to prevent the display from accidentally closing when in use (also referred to as display free down). In other words, while a decreased hinge torque allows for easier opening of the display with a single hand, an increased hinge torque can prevent the display from accidentally closing when in use. Thus, since the hinge torque can be increased, opening the display using a single hand can be difficult, especially as the foldable computing devices become thinner and lighter as compared to past models. Often, a user would use a first hand to turn on or power on the foldable computing device and a second hand to open the display.

In the present disclosure, a power button or switch that is used to power on or turn on a foldable computing device can be modified to perform an additional function, such as unlocking a display and automatically opening the display by a defined amount, which can allow a user to further open the display using the same hand that was used to switch on or power on the foldable computing device. In other words, in the present disclosure, the foldable computing device can be powered on and the display can be unlocked as a result of a single action of selecting the power button or switch to power on or turn on the foldable computing device. This approach can resolve instability issues when unlocking displays, and can be suitable for light and thin design platform solutions.

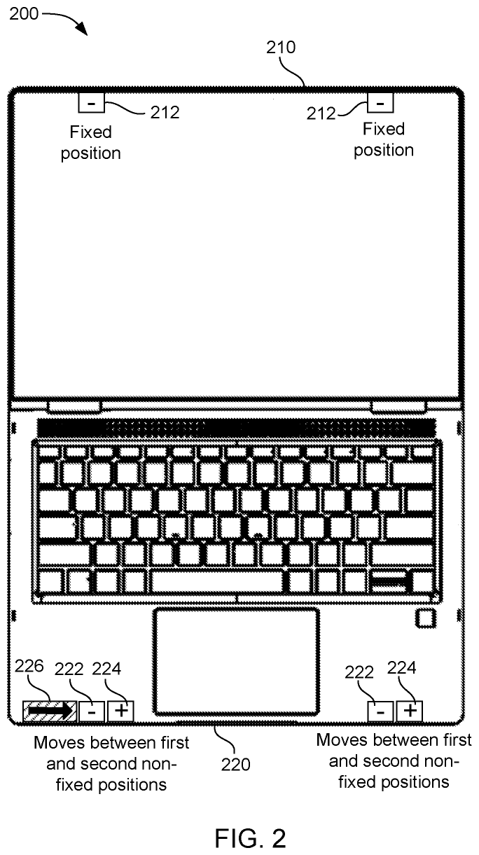

FIG. 2 illustrates an example of a foldable computing device 200 having pairs of magnets to unlock a display screen unit 210 of the foldable computing device 200. For example, the display screen unit 210 can include a first pair of magnets 212, and a base unit 220 of the foldable computing device 200 can include a second pair of magnets 222 and a third pair of magnets 224, which can serve to unlock the display screen unit 210 of the foldable computing device 200. More specifically, the foldable computing device 200 can include an actuator 226, such as a linear piezoelectric actuator, to move the second pair of magnets 222 and the third pair of magnets 224 accordingly to cause the display screen unit 210 to go from locked to unlocked, and vice versa.

In one example, the display screen unit 210 can include the first pair of magnets 212 at a fixed or non-movable position. The first pair of magnets 212 can be at a size that enables the first pair of magnets 212 to fit within the display screen unit 210. The second pair of magnets 222 and the third pair of magnets 224 can be at non-fixed or moveable positions, respectively, where the second pair of magnets 222 and the third pair of magnets 224 can be moved using the actuator 226. In other words, the actuator 226 can produce a linear motion that causes the second pair of magnets 222 and the third pair of magnets 224 to move between a first non-fixed position and a second non-fixed position.

For example, when the second and third pair of magnets 222, 224 is at the first non-fixed position, the first pair of magnets 212 of the display screen unit 210 can be attracted to the third pair of magnets 224, thereby causing the display screen unit 210 to be locked. In other words, an attraction force between the first pair of magnets 212 and the third pair of magnet 224 can cause the display screen unit 210 to be locked. In this example, there can be no or minimal attraction or repulsion force between the first pair of magnets 212 and the second pair of magnets 222, based on the second and third pair of magnets 222, 224 being at the first non-fixed position.

In another example, when the second and third pair of magnets 222, 224 is at the second non-fixed position, the first pair of magnets 212 of the display screen unit 210 can be repulsed by the second pair of magnets 222, thereby causing the display screen unit 210 to become unlocked. In other words, a repulsion force between the first pair of magnets 212 and the second pair of magnets 222 can cause the display screen unit 210 to be locked. In this example, there can be no or minimal attraction or repulsion force between the first pair of magnets 212 and the third pair of magnets 224, based on the second and third pair of magnets 222, 224 being at the second non-fixed position.

In one example, in a default configuration when the display screen unit 210 is locked, the actuator 226 can be at a default position (e.g., not expanded). In this default configuration, the second and third pair of magnets 222, 224 can be at the first non-fixed position, such that a negative end of the first pair of magnets 212 can be attracted to a negative end of the second pair of magnets 222, thereby causing the display screen unit 210 to be locked. When an electrical voltage is applied to the actuator 226, the actuator 226 can expand to cause the second and third pair of magnets 222, 224 to move from the first non-fixed position to the second non-fixed position. When at the second non-fixed position, the negative end of the first pair of magnets 212 can be repulsed by a negative end of the second pair of magnets 222, thereby causing the display screen unit 210 to become unlocked.

In one example, the pairs of magnets included in the foldable computing device 200 can include permanent magnets, including rare-earth magnets. Rare-earth magnets are permanent magnets made from alloys of rare-earth elements. Non-limiting examples of rare-earth magnets include samarium-cobalt magnets and neodymium-iron-boron (NIB) magnets. Alternatively, the pairs of magnets can be made from other magnet types, such as ferrite or alnico magnets.

In one example, the actuator 226 can be a ceramic actuator made from piezoelectric material, which can provide a mechanical attribute when an electrical force is applied to the piezoelectric material. In other words, when an electrical voltage is applied to the actuator 226 made from the piezoelectric material, the actuator 226 can generate a mechanical force. An electrical energy provided to the actuator 226 can be converted into a linear motion, where the linear motion can be used to move the pairs of magnets in the foldable computing device 200 to unlock and lock the display screen unit 210.

Non-limiting examples of piezoelectric material can include, but are not limited to, lithium niobate, lithium tantalite, barium titanate, bismuth ferrite, bismuth titanate, gallium arsenide, zinc oxide, aluminium nitride, lead zirconate-titanate (PZT), sodium bismuth titanate, and polyvinylidene fluoride (PVDF).

In one example, the foldable computing device 200 can be powered on after a power button of the foldable computing device 200 is pressed or selected, at which an electrical pulse or signal can be generated and sent from the power button to the actuator 226. The electrical pulse can cause the actuator 226 to produce a linear motion, thereby causing the actuator 226 to expand. The actuator 226 can be coupled to the second and third pair of magnets 222, 224. Thus, when the actuator 226 expands, this expansion can cause the second and third pair of magnets 222, 224 to move from a first non-fixed position (or a default position when the foldable computing device 200 is shut off and the display screen unit 210 is locked) to a second non-fixed position, at which the foldable computing device 200 is turned on and the display screen unit 210 is unlocked. In this example, the piezoelectric material of the actuator 226 can cause a change between an attraction force and a repulsion force, to unlock the display screen unit 210.

In one configuration, the actuator 226 can be expanded, and the display screen unit 210 can be unlocked and opened. Over a period of time, the actuator 226 can contract back to the default position, such that the second and third pair of magnets 222, 224 can move from the second non-fixed position back to the first non-fixed position. As a result, when the display screen unit 210 is closed, the first pair of magnets 212 can be attracted to the third pair of magnets 224, thereby locking the display screen unit 210.

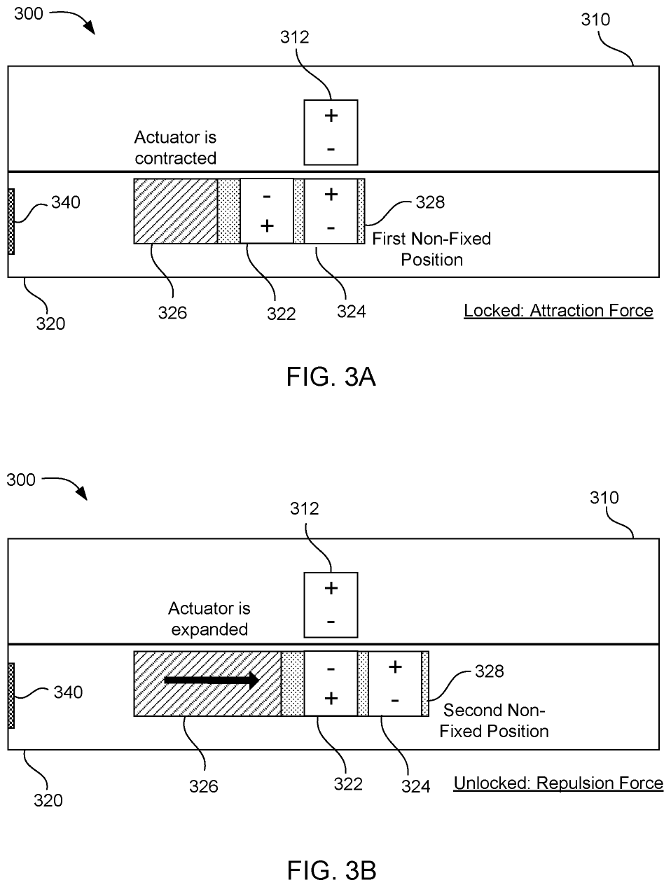

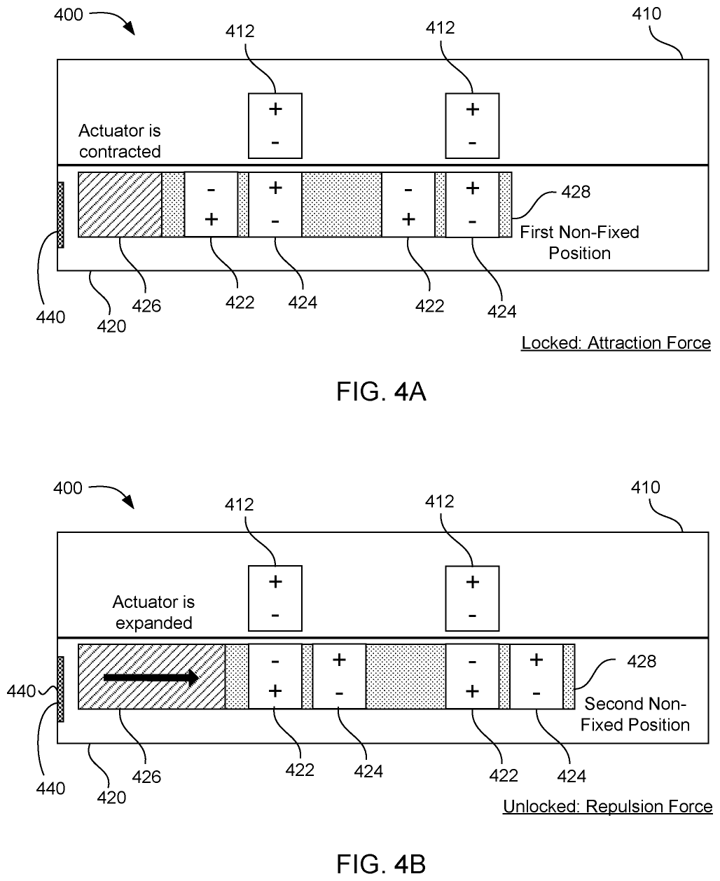

In one configuration, the base unit 220 can include an assembly (shown in FIGS. 3A, 3B, 4A and 4B) that includes the second and third pair of magnets 222, 224. For example, the assembly can be a metal rod to which the second and third pair of magnets 222, 224 are attached. When the actuator 226 is contracted, the assembly with the second and third pair of magnets 222, 224 can be at the first non-fixed position, and the display screen unit 210 can be locked. The actuator 226 can expand to move the assembly with the second and third pair of magnets 222, 224 to the second non-fixed position, and the display screen unit 210 can be unlocked.

In one example, the display screen unit 210 and the base unit 220 can include multiple pairs of magnets, such as three pairs of magnets or four pairs of magnets, which can be used for unlocking and locking the display screen unit 210.

FIG. 3A illustrates an example of a foldable computing device 300 having magnets to lock a display screen unit 310 based on an attraction force. The display screen unit 310 can include a first magnet 312 with a negative end. The foldable computing device 300 can include a base unit 320. The base unit 320 can include an assembly 328. The assembly 328 can include a second magnet 322 with a negative end and a third magnet 324 with a positive end. In addition, the foldable computing device 300 can include an actuator 326, such as a linear piezoelectric actuator.

In one example, the actuator 326 can be attached or coupled to the assembly 328 with the second magnet 322 and the third magnet 324. Thus, a linear motion of the actuator 326 can cause a linear motion of the assembly 328 with the second magnet 322 and the third magnet 324. For example, an expansion of the actuator 326 can cause the assembly 328 with the second magnet 322 and the third magnet 324 to move outwards, whereas a contraction of the actuator 326 can cause the assembly 328 with the second magnet 322 and the third magnet 324 to move inwards.

In one configuration, the assembly 328 with the second magnet 322 and the third magnet 324 can be at a first non-fixed position. The assembly 328 can be at the first non-fixed position when the actuator 326 is contracted. In this configuration, the first magnet 312 can be attracted to the third magnet 324, as the negative end of the first magnet 312 can be attracted to the positive end of the third magnet 324. As a result, the display screen unit 310 can be locked and closed. For example, as a default, the actuator 326 can be contracted and the assembly 328 can be at the first non-fixed position, when the display screen unit 310 is locked and closed.

FIG. 3B illustrates an example of the foldable computing device 300 having magnets to unlock the display screen unit 310 based on a repulsion force. The foldable computing device 300 can include a power button or switch 340, which can be selected to power on or turn on the foldable computing device 300. When the power button or switch 340 is switched on, the foldable computing device 300 can be powered on and an electrical pulse (or electrical signal) can be generated via the power button or switch 340, and the electrical pulse can be sent from the power button or switch 340 to the actuator 326 to cause the actuator 326 to expand. When the actuator 326 is expanded, the assembly 328 with the second magnet 322 and the third magnet 324 can be moved from the first non-fixed position to the second non-fixed position. In this configuration, the first magnet 312 can be repulsed by the second magnet 322, as the negative end of the first magnet 312 can repulse the negative end of the second magnet 322. As a result, the display screen unit 310 can be unlocked and opened.

In one example, as shown, when the assembly 328 with the second magnet 322 and the third magnet 324 is at the first non-fixed position, the second magnet 322 can be away from the first magnet 312 and the third magnet 324 can be attracted to the first magnet 312. In other words, at the first non-fixed position, there is no or minimal attraction and/or repulsion between the first magnet 312 and the second magnet 322. In another example, as shown, when the assembly 328 with the second magnet 322 and the third magnet 324 is at the second non-fixed position, the third magnet 324 can be away from the first magnet 312 and the second magnet 322 can be repulsed by the first magnet 312.

In other words, at the second non-fixed position, there is no or minimal attraction and/or repulsion between the first magnet 312 and the third magnet 324.

In one example, when the display screen unit 310 is unlocked, the display screen unit 310 can be opened by a defined amount. As a non-limiting example, the display screen unit 310 can open between a few millimeters to a few inches, at which point a user can manually open the display screen unit 310 further using a single hand.

In one configuration, the power button or switch 340 can be selected and the display screen unit 310 can be unlocked and opened in a near simultaneous manner. In other words, from a perspective of a user, the user can select the power button or switch 340 to power on or turn on the foldable computing device 300, and the display screen unit 310 can near instantly be unlocked and opened by the defined amount. For example, after the power button or switch 340 is selected, the display screen unit 310 can be unlocked and opened less than two seconds later, less than one second later, less than 0.5 seconds later, less than 0.25 seconds later, or so on.

In one configuration, after the display screen unit 310 is unlocked, the actuator 326 can contract back to a default or original position. When the actuator contracts back to the default position, the assembly 328 can move from the second non-fixed position back to the first non-fixed position. As a result, when a user attempts to close the display screen unit 310 by pushing the display screen unit 310 down, the first magnet 312 can attract to the third magnet 324, which can allow for the display screen unit 310 to be locked.

FIG. 4A illustrates an example of a foldable computing device 400 having pairs of magnets to lock a display screen unit 410 based on an attraction force. The display screen unit 410 can include a first pair of magnets 412 with a negative end. The foldable computing device 400 can include a base unit 420. The base unit 420 can include an assembly 428. The assembly 428 can include a second pair of magnets 422 with a negative end and a third pair of magnets 424 with a positive end. In addition, the foldable computing device 400 can include an actuator 426, such as a linear piezoelectric actuator.

In one example, the actuator 426 can be attached or coupled to the assembly 428 with the second pair of magnets 422 and the third pair of magnets 424.

Thus, a linear motion of the actuator 426 can cause a linear motion of the assembly 428 with the second pair of magnets 422 and the third pair of magnets 424. For example, an expansion of the actuator 426 can cause the assembly 328 with the second pair of magnets 422 and the third pair of magnets 424 to move outwards, whereas a contraction of the actuator 426 can cause the assembly 428 with the second pair of magnets 422 and the third pair of magnets 424 to move inwards.

In one configuration, the assembly 428 with the second pair of magnets 422 and the third pair of magnets 424 can be at a first non-fixed position. The assembly 428 can be at the first non-fixed position when the actuator 426 is contracted. In this configuration, the first pair of magnets 412 can be attracted to the third pair of magnets 424, as the negative end of the first pair of magnets 412 can be attracted to the positive end of the third pair of magnets 424. As a result, the display screen unit 410 can be locked and closed. For example, as a default, the actuator 426 can be contracted and the assembly 428 can be at the first non-fixed position, when the display screen unit 410 is locked and closed.

FIG. 4B illustrates an example of the foldable computing device 400 having magnets to unlock the display screen unit 410 based on a repulsion force. The foldable computing device 400 can include a power button or switch 440, which can be selected to power on or turn on the foldable computing device 400. When the power button or switch 440 is switched on, the foldable computing device 400 can be powered on and an electrical pulse can be generated and sent to the actuator 426 to cause the actuator 426 to expand. When the actuator 426 is expanded, the assembly 428 with the second pair of magnets 422 and the third pair of magnets 424 can be moved from the first non-fixed position to the second non-fixed position. In this configuration, the first pair of magnets 412 can be repulsed by the second pair of magnets 422, as the negative end of the first pair of magnets 412 can repulse the negative end of the second pair of magnets 422. As a result, the display screen unit 410 can be unlocked and opened.

In one configuration, the foldable computing device 400 can have more than one actuator (e.g., linear piezoelectric actuator) and more than one assembly. For example, the foldable computing device 400 can include a first assembly, one of a second pair of magnets, one of a third pair of magnets, and a first actuator. Similarly, the foldable computing device 400 can include a second assembly, the other of the second pair of magnets, the other of the third pair of magnets, and a second actuator. In this configuration, the separate actuators can separately but simultaneously move the two assemblies to cause attraction or repulsion between the pairs of magnets, thereby unlocking or locking the foldable computing device 400.

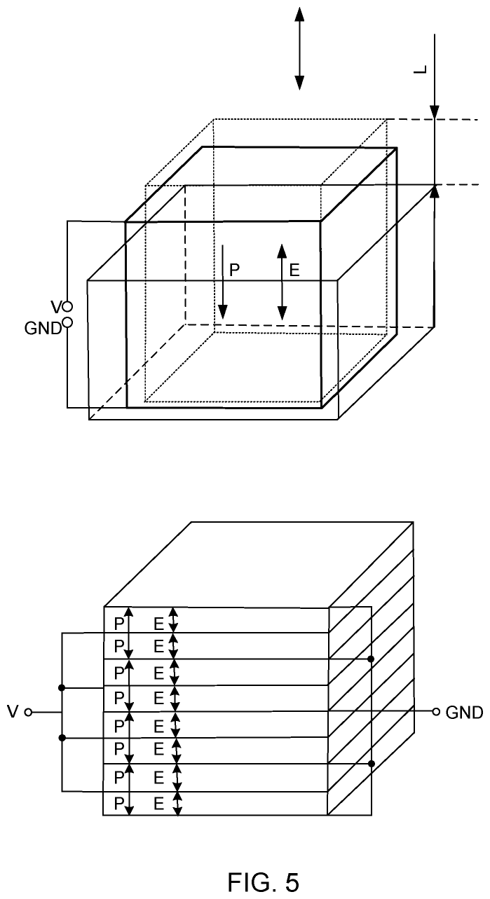

FIG. 5 illustrates an example of a functionality of a piezoelectric actuator having a stacked structure. As shown, a longitudinal displacement can occur at the piezoelectric actuator, and individual piezoelectric elements of the piezoelectric actuator having the stacked structure can have a defined polarization (P). A piezoelectric element can be a ceramic element that expands or contracts when an electrical charge is applied, thereby generating linear movement and force. In this example, multiple piezoelectric elements can be layered on top of each other, to create the piezoelectric actuator having the stacked structure.

In one example, the individual piezo elements in the piezoelectric actuator having the stacked structure can have an alternating polarity (e.g., alternating between positive and negative polarity). When a voltage (V) is applied, the longitudinal displacement can occur in a direction of polarization. Further, an electrical field (E) can be applied parallel to the direction of polarization. In one example, a movement of a piezoelectric element can equal an amount of voltage applied multiplied by a piezoelectric electric coefficient. The piezoelectric electric coefficient can relate to the material's efficiency in transferring electrical energy to mechanical energy. Since the individual piezoelectric elements can be connected mechanically in series, a total movement of a stacked piezoelectric actuator can be a product of a single element's movement, times a number of elements in the stack. A total displacement of the stacked piezoelectric actuator can be a percentage (e.g., between 0.1 and 0.15 percent) of a length (L) of the stacked piezoelectric actuator.

As an example, when a voltage is applied in a direction of polarization, a displacement can be produced, and in a stacked piezoelectric actuator, a total displacement can be the sum of each layer's individual displacement. Thus, the stacked piezoelectric actuator can convert electrical energy to a mechanical energy through a piezoelectric effect.

In one example, piezoelectric materials can include, but are not limited to, lithium niobate, lithium tantalite, barium titanate, bismuth ferrite, bismuth titanate, gallium arsenide, zinc oxide, aluminium nitride, lead zirconate-titanate (PZT), sodium bismuth titanate, and polyvinylidene fluoride (PVDF).

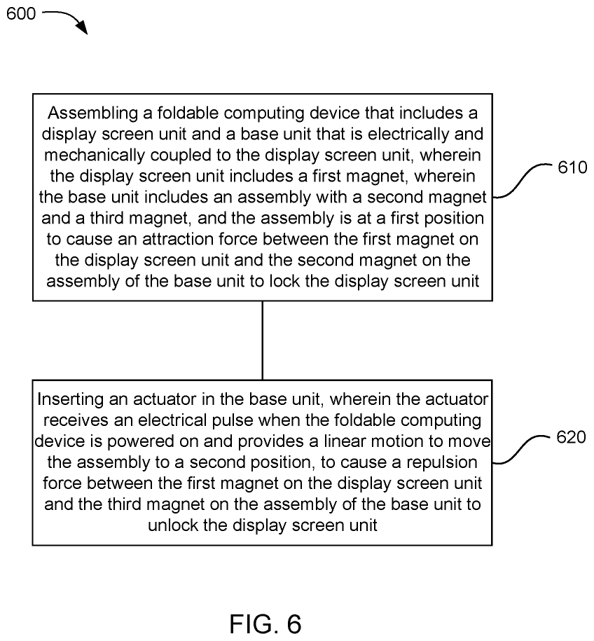

FIG. 6 is a flowchart illustrating one example method 600 of making a foldable computing device. The method can include assembling a foldable computing device that includes a display screen unit and a base unit that is electrically and mechanically coupled to the display screen unit, wherein the display screen unit includes a first magnet, wherein the base unit includes an assembly with a second magnet and a third magnet, and the assembly is at a first position to cause an attraction force between the first magnet of the display screen unit and the second magnet of the assembly in the base unit to lock the display screen unit, as in block 610. The method can include inserting an actuator in the base unit, wherein the actuator receives an electrical pulse when the foldable computing device is powered on and provides a motion to move the assembly to a second position, to cause a repulsion force between the first magnet of the display screen unit and the third magnet of the assembly in the base unit to unlock the display screen unit, as in block 620.

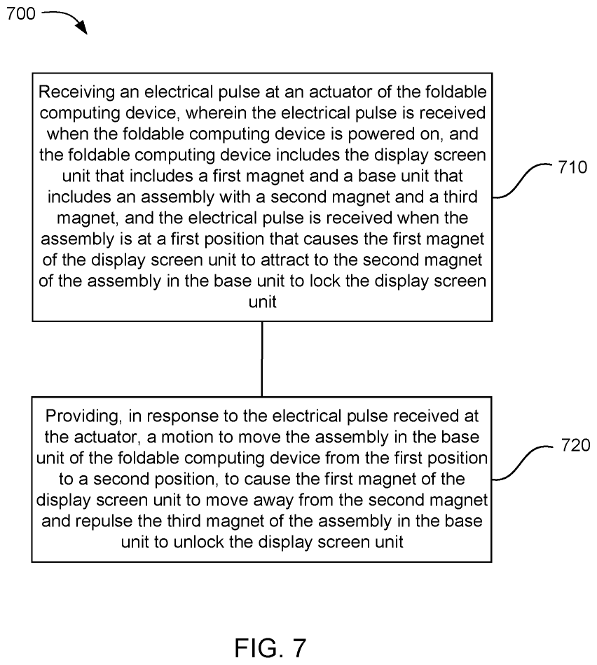

FIG. 7 is a flowchart illustrating one example method 600 of unlocking a display screen unit in a foldable computing device. The method can include receiving an electrical pulse at an actuator of the foldable computing device, wherein the electrical pulse is received when the foldable computing device is powered on, and the foldable computing device includes the display screen unit that includes a first magnet and a base unit that includes an assembly with a second magnet and a third magnet, and the electrical pulse is received when the assembly is at a first position that causes the first magnet of the display screen unit to attract to the second magnet of the assembly in the base unit to lock the display screen unit, as in block 710. The method can include providing, in response to the electrical pulse received at the actuator, a motion to move the assembly in the base unit of the foldable computing device from the first position to a second position, to cause the first magnet of the display screen unit to move away from the second magnet and repulse the third magnet of the assembly in the base unit to unlock the display screen unit, as in block 720.

While the flowcharts presented for this disclosure can imply a specific order of execution, the order of execution can differ from what is illustrated. For example, the order of two more blocks can be rearranged relative to the order shown. Further, two or more blocks shown in succession can be executed in parallel or with partial parallelization. In some configurations, block(s) shown in the flow chart can be omitted or skipped. A number of counters, state variables, warning semaphores, or messages can be added to the logical flow for purposes of enhanced utility, accounting, performance, measurement, troubleshooting or for similar reasons.

Reference was made to the examples illustrated in the drawings, and specific language was used herein to describe the same. It will nevertheless be understood that no limitation of the scope of the disclosure is thereby intended. Alterations and further modifications of the features illustrated herein, and additional applications of the examples as illustrated herein, are to be considered within the scope of the description.

Furthermore, the described features, structures, or characteristics can be combined in a suitable manner. In the preceding description, numerous specific details were provided, such as examples of various configurations to provide a thorough understanding of examples of the described disclosure. The disclosure may be practiced without some of the specific details, or with other methods, components, devices, etc. In other instances, some structures or operations are not shown or described in detail to avoid obscuring aspects of the disclosure.

Although the subject matter has been described in language specific to structural features and/or operations, it is to be understood that the subject matter defined in the appended claims is not limited to the specific features and operations described above. Rather, the specific features and acts described above are disclosed as example forms of implementing the claims. Numerous modifications and alternative arrangements can be devised without departing from the scope of the described disclosure.

What is claimed is:

1. A foldable computing device, comprising:
a power switch;
a display screen unit including a first magnet;
a base unit electrically and mechanically coupled to the display screen unit, the base unit including an assembly with a second magnet and a third magnet, wherein the assembly is at a first position that causes the first magnet of the display screen unit to attract to the second magnet of the assembly in the base unit to lock the display screen unit; and
an actuator that receives an electrical pulse when the power switch is selected to power on the foldable computing device and provides a motion to move the assembly to a second position, to cause the first magnet of the display screen unit to be moved away from the second magnet and repulse the third magnet of the assembly in the base unit to unlock the display screen unit.

2. The foldable computing device of claim 1, wherein the first magnet incudes a first pair of magnets, the second magnet includes a second pair of magnets, and the third magnet includes a third pair of magnets.

3. The foldable computing device of claim 1, wherein the actuator is a linear piezoelectric actuator that causes the motion produced by the actuator to be linear.

4. The foldable computing device of claim 1, wherein the actuator contracts to move the assembly to the first position after the display screen unit is unlocked and opened, to enable the display screen unit to be locked when the first magnet becomes attracted to the second magnet of the assembly in the base unit.

5. The foldable computing device of claim 1, wherein the foldable computing device is powered on and the display screen unit is unlocked as a result of a single action of selecting the power switch to power on the foldable computing device.

6. The foldable computing device of claim 1, wherein the display screen unit opens by a defined amount when the display screen unit is unlocked.

7. The foldable computing device of claim 1, wherein the first magnet includes a negative end that attracts to a positive end of the second magnet to lock the display screen unit.

8. The foldable computing device of claim 1, wherein the first magnet includes a negative end that is repulses a negative end of the second magnet to unlock the display screen unit.

9. A method of making a foldable computing device, comprising:
assembling a foldable computing device that includes a display screen unit and a base unit that is electrically and mechanically coupled to the display screen unit, wherein the display screen unit includes a first magnet, wherein the base unit includes an assembly with a second magnet and a third magnet, and the assembly is at a first position to cause an attraction force between the first magnet of the display screen unit and the second magnet of the assembly in the base unit to lock the display screen unit; and
inserting an actuator in the base unit, wherein the actuator receives an electrical pulse when the foldable computing device is powered on and provides a motion to move the assembly to a second position, to cause a repulsion force between the first magnet of the display screen unit and the third magnet of the assembly in the base unit to unlock the display screen unit.

10. The method of claim 9, wherein the first magnet incudes a first pair of magnets, the second magnet includes a second pair of magnets, and the third magnet includes a third pair of magnets.

11. The method of claim 9, wherein the actuator is a linear piezoelectric actuator that causes the motion produced by the actuator to be linear.

12. The method of claim 9, wherein the actuator contracts to move the assembly to the first position after the display screen unit is unlocked and opened, to enable the display screen unit to be locked when the first magnet becomes attracted to the second magnet in the assembly of the base unit.

13. The method of claim 9, wherein the foldable computing device is powered on and the display screen unit is unlocked as a result of a single action of selecting the power switch to power on the foldable computing device.

14. A method of unlocking a display screen unit in a foldable computing device, comprising:
receiving an electrical pulse at an actuator of the foldable computing device, wherein the electrical pulse is received when the foldable computing device is powered on, and the foldable computing device includes the display screen unit that includes a first magnet and a base unit that includes an assembly with a second magnet and a third magnet, and the electrical pulse is received when the assembly is at a first position that causes the first magnet of the display screen unit to attract to the second magnet of the assembly in the base unit to lock the display screen unit; and
providing, in response to the electrical pulse received at the actuator, a motion to move the assembly in the base unit of the foldable computing device from the first position to a second position, to cause the first magnet of the display screen unit to move away from the second magnet and repulse the third magnet of the assembly in the base unit to unlock the display screen unit.

15. The method of claim 14, wherein the actuator is a linear piezoelectric actuator that causes the motion produced by the actuator to be linear.
